(19) United States
(12) Patent Application Publication
(10) Pub. No.: US 2001/0007578 A1
(43) Pub. Date: Jul. 12, 2001

(54) Method and system for encoding data for transmission channels

(76) Inventors: Moshe Ran, Re'ut (IL); Shahaf Israel Wayer, Tel Aviv (IL)

Correspondence Address: Robert D. Buyan, Stout, Uxa, Buyan & Mullins, LLP, 4 Venture, Suite 300, Irvine, CA, 92618, US

(21) Appl. No.: 09/755,209

(22) Filed: Jan. 5, 2001

(30) Foreign Application Priority Data
Jan. 6, 2000 (IL) 133896

(51) Int. Cl. H04B 14/04

(52) U.S. Cl. 375/253

(57) ABSTRACT

A method and system for encoding data for transmission over a transmission channel in a digital communication system, the method including selecting an appropriate variable length product code for variable length data to be transmitted, and encoding the data by means of the selected product code. The system includes a code selecting unit arranged to select a variable length code which is most suitable for variable length data to be encoded, and an encoder encoding the variable length data with the selected variable length product code.

### FIELD OF THE INVENTION

The present invention relates to a method and system for encoding data for transmission channels in a digital communications system in general and, in particular, to a method for encoding variable length data, which provides improved error protection and the possibility to employ robust soft-decision decoding.

### BACKGROUND OF THE INVENTION

Many communications systems are used at present to transmit information from a source to a destination via a transmission channel, such as air, i.e., wireless communication, wired communication, such as copper telephony lines or coaxial cable, fiber optic, and HFC (Hybrid Fiber Coax), computer memory, under water channels, etc.

A general example of a system wherein variable length packets are transmitted over a communication channel, is shown in FIG. 1. The system includes a base station 9 coupled for communication over a channel interface 7 to a plurality of subscriber or user stations 5. Typically, the forward channel in these communication systems is a point-to-multipoint (P-MP) transmission from base station to the subscribers units. The base station serves as a radio resource supervisor. It may provide messages, through an appropriate air interface, to configure the transceiver of the subscriber unit.

Generally, the data in the reverse channel is transmitted from multiple subscriber units to the base station unit using variable length bursts of data containing k bytes of information, where k can vary between a few bytes to several hundreds of bytes. Each subscriber unit is likely to have different channel conditions and thus requires different error protection capabilities against channel impairments. Examples of the expected channel impairment in these wireless systems are: time-variant impairments, multipath, interference from other users, rain fade, etc. Different distortions are expected in coax channels, fiber optical channels and HFC channels.

It is often desired that the set of functions or services offered to a user meet certain performance criteria, which will reflect the satisfaction of a user of the service. This set of performance criteria, sometimes called quality of service (QoS), includes minimum error rate, maximum allowable delay and the amount of the communication channel capacity in bits per seconds available to a user for services.

Methods like adaptive-bandwidth and adaptive-rate modulations are known in the art of modem techniques for improving the reliability of transmission in both directions: base stations to subscribers and from multiple subscribers to base station. This methodology can be summarized in the following steps:

1) the subscriber selects an optimum transmission bandwidth, say W Hz;

2) the subscriber and the base station negotiate to meet the Quality of Service requirements over this bandwidth;

3) the base station sends the subscriber configuration parameters established for the communication according to the results of the negotiation;

4) the subscriber sends (or accepts) W symbols/second.

A number of communication protocols are in use today for transporting variable length packets over the transmission channel. Internet Protocol (IP) is one example of such a communication protocol service. While the average packet size in some 90% of IP transmissions varies from 40 to 400 bytes, IP traffic of 552 bytes, 576 and 1500 bytes is not uncommon. Another service that makes use of variable length frame format is frame relay circuit-based data protocol.

Generally, data to be transmitted undergoes both source coding and channel coding. Source coding forms an efficient binary representation of the signal to be transmitted, with minimum distortion. Channel coding, on the other hand, serves to protect the data bits against perturbations during transmission over the transmission channel. In most instances, it has been deemed to be sufficient to detect errors in transmission. In these cases, ARQ (Automatic Repeat Request) has been utilized, which detects transmission errors and requests retransmission if error is detected. However, when the transmission conditions are more difficult and create significant signal distortion, and in cases when there is no possibility of retransmission, such as a broadcast which has no reverse channel, error detection is not enough. Error correction is required.

Error correction for data protocols which transmit packets over transmission channels has been provided by various Error Control Coding (ECC) schemes. The most common schemes include block codes, convolutional codes or concatenation of both. Other methods of error correction include a combination of coding and modulation. This technique transforms code words into Euclidean space code words, where the Euclidian distance between code words is large, and proportional to the Hamming distance between the code words. Yet another method for achieving maximum utilization of the capacity of the channel includes using appropriate error correction code and adaptive rate/adaptive modulation.

Block coding consists of adding n-k redundancy bits or symbols to k information bits or symbols originating from the source coding, and using these redundancy bits or symbols in the receiver, in order to correct certain transmission errors. A block code is a linear block code if it is a linear subspace of the vector space containing all possible n-tuples of symbols over some given alphabet. That means that the sum and difference of every pair of code words is in the code. (n, k, d) defines a linear block code of length n, dimension k, and minimum Hamming distance d. The ratio R=k/n is known as the code rate, and indicates the efficiency of the code. For purposes of this invention, the last parameter, d, is dropped, and the code is referred to as (n, k) block code, which is generally a linear block code, although the block code can also be non-linear for use in the invention. The most commonly used block code is Reed-Solomon code which is defined over a finite alphabet which is required to be a finite field with q elements. In most practical applications, q<256.

(n₁, k₁, d₁)×(n₂, k₂, d₂) is a general representation of a block code with length n=n₁n₂, dimension k=k₁k₂, and minimum distance d=d₁d₂. The code constructed in this way is called a product code (or 2-D array code), and (nᵢ, kᵢ) for i=1,2 are called the component codes. The code words of the product code can be described by an n₁ times n₂ rectangular array, where the columns are code words of code (n₁, k₁) and the rows are code words of (n₂, k₂). This idea can be generalized straightforward to 3-D array codes based on three components code (nᵢ, kᵢ) for i=1,2,3.

One common conventional technique to adapt the length of the code to the desired length of the data is by shortening the code. By that we mean that some sequence of, say, S data symbols out of k information symbols are set at zero, then the encoder adds the n-k redundant symbols. During transmission, these S symbols are ignored.

The coding gain, expressed in decibels, at a given bit error rate (BER), is defined as the difference between E_{b}/N₀ uncoded and E_{b}/N₀ with coding, where E_{b} is the normalized energy per information bit, and N₀ is the normalized noise power density. It is desirable that the coding gain and the efficiency of the code be as high as possible, while preferably, the complexity of decoding will be as low as possible.

A decoder in the receiver is used to estimate the original message based on the received data. A number of methods have been implemented for decoding coded information transmitted in packets. The simplest method is known as bounded distance hard decision decoding. In this method, the decoder finds the closest code word to the hard detected received vector, only in a sphere of radius t defined as the correction capability of the code. Most of the decoders implemented today belong to the class of bounded distance hard decision decoders, including the decoder for Reed-Solomon code. This method is not optimal in the sense that the search for the best code word is limited to a small set of code words around a received word (vector).

A better strategy would allow one to find the closest code word from the entire space of the code. Such an optimal strategy would require a full search over a large number of possible code words. This method is called maximum likelihood (MLD) hard detection. From the point of view of complexity, it is possible to carry out this process only for very short codes. For example, for a Reed-Solomon code whose parameters (n,k,d) are n=204, k=188, q=256, the complexity is 256¹⁸⁸, which is impossible to carry out even with a powerful computer.

Soft decision decoding utilizes all the information in the received data symbol stream, including a value assigned by the hard decision decoding to the particular received bit in the symbol, and an estimate of the channel information associated with this bit. This estimate indicates the reliability that the value assigned by the hard decision decoding to the particular received bit in the symbol is correct. A larger real number indicates a more reliable decision. Soft-In/Soft-Out (SISO) iterative decoding uses, in addition, information gained during iteration to update the reliabilities associated with each bit. Several soft decision decoding algorithms are known. First, MLD soft (Maximum Likelihood Soft) which is the brute force method, and is an optimal process (finds the closes code word). For each received vector, the closest code word, in Euclidean distance, is found. This method is even more complex than the MLD hard decoding, and cannot be carried out.

L. R. Bahl, J. Cocke, F. Jelinek, and J. Raviv, “Optimal Decoding of Linear Codes for minimizing symbol error rate”, IEEE Transactions Information Theory, p.284-287 (1974), describe another soft optimal decision decoding process, referred to as BCJR. Here, the authors use symbol-by-symbol soft decision decoding to find the code word bring the maximum a posteriori probability (MAP) (minimum symbol-by-symbol distortion).

Other soft decision decoders are known which are sub-optimal, meaning that they do not search through all the possible code words. These include the Generalized Minimum Distance (GMD) algorithm of G. D. Forney, “Generalized Minimum Distance Decoding”, IEEE Trans. Information Theory, p. 125-131 (1966), and the algorithms of D. Chase, “A Class of Algorithms for Decoding Block Codes with Channel Measurement Information”, IEEE Trans. Information Theory 170-182 (1972). These algorithms are in frequent use in the field of block codes.

Iterative soft decision decoding is described in an article by J. Lodge et al, “Separable MAP filters for the decoding of product and concatenated codes”, Proc. ICC'93, Geneva, pages 1740-1745, May 1993. They proposed an iterative decoding algorithm comprising the following steps: decoding the columns by using the BCJR algorithm, which estimates the logarithmic likelihood ratios (LLR) of the bits; decoding the rows by using the BCJR algorithm and by taking, as input data, the likelihoods (LLR) calculated during the decoding of the columns; and recommencing the decoding of the columns with, as input data, the likelihoods (LLR) calculated during the decoding of the lines.

Iterative decoding is also discussed in several patents, for example, U.S. Pat. No. 5,563,897 to Pyndiah et al. This patent proposes a method for detecting information bits in a coded digital signal, within a receiver, the coding of the digital signal having been performed within a transmitter by applying, to information bits to be transmitted, a block code corresponding to the product of at least two elementary systematic block codes, the method including an iterative decoding phase including a number m of decoding cycles, each decoding cycle successively including code word search steps for each elementary block code used in the product code. Pyndiah uses sub-optimal soft decision decoding for decoding component code.

There is known from U.S. Pat. No. 5,930,272 to Thesling another sub-optimal method for soft decision decoding a linear block code of information bits to produce soft output information, including the steps of receiving the transmitted signals and converting the received signals into a number of received vectors r having a length of n; and for each vector r, performing hard decisions on r to produce a hard decision data vector and a corresponding reliability information vector, performing hard decision decoding on the data vector into a center code word, the reliability vector and center word both having a length n, identifying a set of nearby code words including the center code word, determining, for each nearby code word, a difference metric, identifying a minimum difference metric and determining an output code word as being that code word corresponding to this minimum difference metric, and assigning a confidence measure for each bit in the output code word.

In short, prior art Error Control Coding schemes suffer from a number of disadvantages. In particular, Reed-Solomon codes, the most commonly used codes, are limited to a length of 256 bytes, which is not optimized for present IP traffic. In addition, the decoder for Reed-Solomon codes is essentially a bounded hard distance decoder. Thus, soft decision decoding, which dramatically improves performance, cannot be utilized with these conventional coding systems. Furthermore, none of the prior art known to applicant addresses the issue of optimizing the length of the product encoder for data packets of varying lengths.

### SUMMARY OF THE INVENTION

An object of the present invention is to provide a method for protecting variable length packets of data against channel errors. The method is based on encoding the data by means of a configurable product code, resulting in controllable decoding complexity and efficiency.

There is thus provided in accordance with the present invention a method for encoding data for transmission over a transmission channel in a digital communication system, the method including selecting an appropriate variable length product code for variable length data to be transmitted, and encoding the data by means of the selected product code.

According to a preferred embodiment, the variable length product code is selected in accordance with parameters selected from size of data packet, Quality of Service terms, and channel conditions at the time of transmission.

According to one embodiment of the invention, the method further includes transferring the encoded data packets over the transmission channel by means of a data protocol.

According to a preferred embodiment of the invention, the data is encoded in such a way as to provide scalable decoder complexity.

According to one embodiment of the invention, the step of encoding includes encoding data by means of a Hamming product code.

Further according to this embodiment, the step of encoding includes selecting the product code by means of the following algorithm:

Algorithm 1:

Finding the preferred block dimensions for a given data length

Let K be the data length (in bits), then the algorithm finds a factorization K=k₁×k₂ such that for k₁≧k₂ the dimension ratio k₂/k1 is maximum

Start with k₁=Round(Sqrt(K)), k₂=k₁.

If Reminder(K/k₁)=0 then k₂=K/k₁—FINISH (go to 7).

Set k₂=k₂−1.

If Reminder(K/k₂)=0 then k₁=K/k2—FINISH (go to 7).

Set k₁=k₁+1.

If k₂>0 go to (2).

Output k₁, k₂.

There is also provided in accordance with the present invention a system for encoding data for transmission over a transmission channel in a digital communication system, the system for encoding including a code selecting unit arranged to select a variable length code which is most suitable for variable length data to be encoded, and an encoder encoding the variable length data with the selected variable length product code.

According to a preferred embodiment, the code selecting unit includes means for receiving parameters selected from size of data packet, Quality of Service terms, and channel conditions in order to selected said selected code.

According to one embodiment of the invention, the system for encoding further includes a variable length product decoder arranged to decode the encoded data, and a decoding method selecting unit for selecting a method for the variable length product decoder of decoding from the group consisting of hard decision decoding, soft decision decoding, and iterative soft decision decoding.

According to one application of the invention, the digital communication system includes a base station and at least one subscriber unit, and the encoder is mounted in the subscriber unit, wherein the base station includes a code selecting unit arranged to select a code which is most suitable for the data to be encoded, and a transceiver for transmitting the selected code to the encoder in the subscriber unit.

Further according to this application, the base station further includes a variable length product decoder arranged to decode the encoded data, and a decoding method selecting unit for selecting a method of decoding for the variable length product decoder from the group consisting of hard decision decoding, soft decision decoding, and iterative soft decision decoding.

There is also provided in accordance with an embodiment of the present invention a data decoder including a variable length product decoder, including apparatus for performing hard decision decoding, soft decision decoding, and SISO iterative decoding; and a mechanism for selecting one of said methods of decoding for a received data packet.

### BRIEF DESCRIPTION OF THE DRAWINGS

The system and method of the present invention will be further appreciated and understood from the following detailed description in conjunction with the drawings in which:

FIG. 1 is a block diagram of a prior art point-to-multipoint communication system;

FIG. 2a is a block diagram illustration of a transceiver which generates a variable length product code constructed and operative in accordance with one embodiment of the present invention;

FIG. 2b is a block diagram illustration of a decoder constructed and operative in accordance with one embodiment of the present invention designed to recover data encoded by the encoder of FIG. 2a; and

FIG. 3 is a schematic illustration of an encoding matrix according to one embodiment of the present invention.

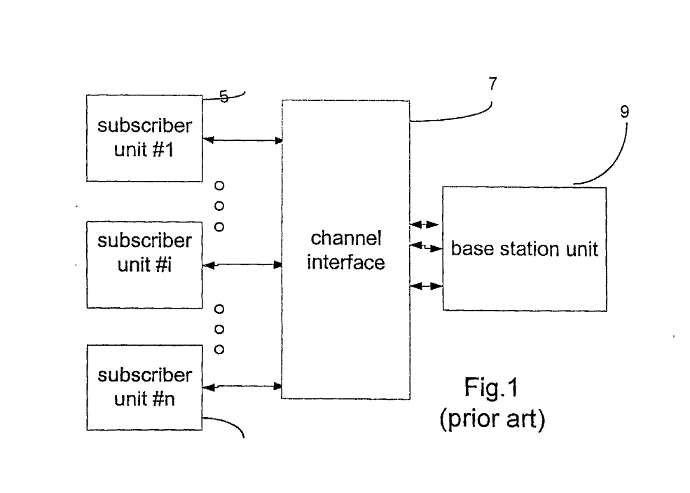

### DETAILED DESCRIPTION OF THE INVENTION

The present invention relates to a method and system for protecting variable length packets of data against channel errors in a communication system. The method is based on encoding the data by means of a configurable product code, resulting in controllable, scalable decoding complexity and greater efficiency. The present invention changes the rate of code and method of decoding, so as to provide adaptive complexity and adaptive coding gain.

One embodiment of the invention applies to a method of constructing a variable length product code for protection of variable length data packets transmitted over a channel in a digital communication system and a method for dynamically encoding information bits in a digital communication system by a variable length product code and a scalable decoder complexity. According to the invention, the optimum code can be calculated in any case where packets of variable length are transmitted.

The present invention is also directed to providing a configurable error protection for a protocol which transports variable length packets over the channel interface. For purposes of the invention, a protocol includes a set of rules that governs the exchange of messages between layers in any of the protocol stacks of a transmitter and a receiver. Thus, the invention applies to all protocols utilizing variable length packets, such as IP (Internet Protocol), and Voice over IP, as well as TCP/IP and other protocols.

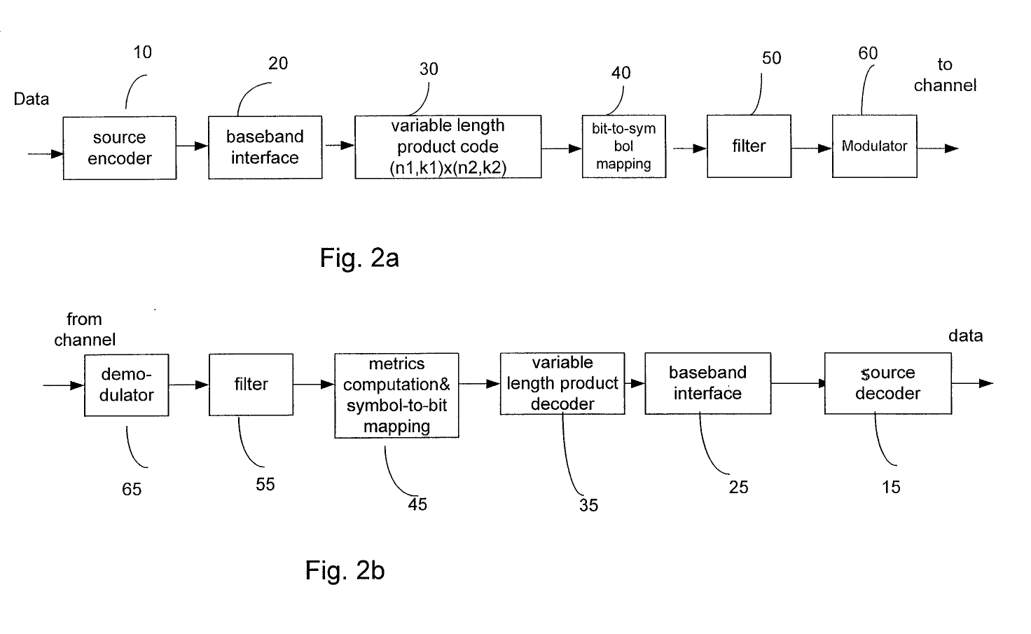

Referring now to FIG. 2a, there is shown a block diagram illustration of a transceiver constructed and operative in accordance with one embodiment of the present invention which generates a sequence of code words using a variable length product code. The transceiver includes a source encoder 10 for providing the appropriate encoding of the source data stream. The encoded data stream passes through a baseband interface 20, which prepares the variable length data packets for possible burst transmission, including addition of preambles and possibly randomization of the bit stream.

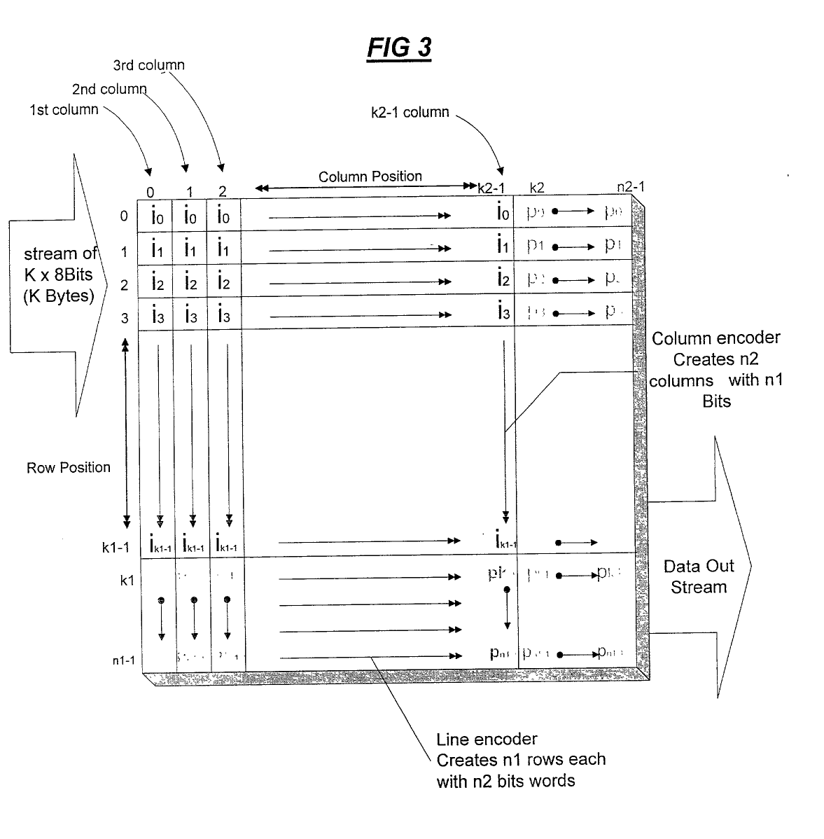

The prepared packets are now input into a variable length product code encoder and interleaver 30, whose operation is illustrated in FIG. 3. Encoder and interleaver 30 consists of a rectangular array of n₁×n₂ bits. The block encoder accepts k₁ bits of data, which are written in the first column of the array, where the last bit is regarded as the MSB (Most Significant Bits). A sequence of n₁−k₁ parity check bits is computed, based on the encoding rule for the column encoder. This procedure is repeated, column by column, until the first k₂ columns of the encoder array are full. When this process, called column encoding, is completed, a row encoding process begins, from the first row to the last row of the array, namely the n₁ row. In this process, every information bit is encoded twice, once in a column and once in a row.

Alternatively, it is possible to shorten the code in order to build the product code so as to match the code size to the required packet length. S1 is the number of bits by which each column is shortened, and S2 is the number of bits by which each row is shortened. In this case, a sequence of S1 bits of zeros, followed by k₁−S1 bits of data are input to the encoder and written in the first column of the array. The parity check bits are computed by taking into account the k₁ bits (k₁−S1 data bits and S1 zeros). This procedure is repeated, column by column, until k₂−S2 columns are filled. Now the row encoding process begins, from the first row to the last row of the array. In each row, k₂−S2 information bits are already entered. Now S2 zeros are added to each row, after which n₂−k₂ parity check bits are written to each row, until all the rows are filled.

With further reference to FIG. 2a, the coded bits are read from the array row by row, in a bit-to-symbol Gray mapping unit 40. Thus, the data is Gray mapped to symbols in the constellation map, as known. The symbols are shaped in a filter 50, such as a root raised cosine filter, with a given roll-off factor, as known in the art. Finally, the filtered symbols are modulated in a modulator 60 and sent to a transmission channel for transmission, as known.

In order to implement the present invention with minimal implementation complexity, a preferred to use same hardware for the column decoder and the row decoder. Therefore, it is preferred to select a product code, which corresponds to the length of the data packet, in a way that the column encoder and the row encoder have approximately the same dimension. This permits the use of the same code for both column encoding and row encoding. The code giving this preferred result can be calculated according to the following algorithm.

Algorithm 1

Finding the preferred block dimensions for a given data length

Let K be the data length (in bits), then the algorithm finds a factorization K=k₁×k₂ such that for k₁≧k₂ the dimension ratio k₂/k₁ is maximum

1. Start with k₁=Round(Sqrt(K)), k₂=k₁.

2. If Reminder(K/k₁)=0 then k₂=K/k₁—FINISH (go to 7).

3. Set k₂=k₂−1.

4. If Reminder(K/k₂)=0 then k₁=K/k₂—FINISH (go to 7).

5. Set k₁=k₁+1.

6. If k₂>0 go to (2).

7. Output k₁, k₂.

It will be appreciated that this algorithm can be adjusted to take into account other desired parameters, such as permitted delay, bit-interleaver, and decoding complexity. In many cases, it is possible to find codes (n₁, k₁), (n₂,k₂) with the desired parameters in existing tables of best known codes. This is sufficient when the decoding method is soft decoding. However, for constructing the best product code which is to be decoded by iterative soft decoding, the complete weight distribution of the code is more important than minimum Hamming distance, especially the number of code words in the code with minimum Hamming distance.

It is known that Hamming Product Code is particularly suited for product code with iterative decoding, despite the fact that its minimum Hamming distance is relatively small. In addition, component codes which are Hamming code have particularly efficient decoders, as their GMD and Chase algorithms are very simple. In a typical application of the invention, variable data packets of length from 18 to 399 bytes are constructed based on Hamming codes as component codes of a 2-D product code. These codes construct a family denoted HPC(m1,m2,S1,S2). This product code has a column component code whose length is n₁=2^{m1}−S1, and whose dimension is k₁=2^{m1}−1−m1−S1, and a row component code whose length is n₂=2^{m1}−S1, and whose dimension is k₂=2^{m2}−1−m2−S2.

Hamming Product Code values can be calculated from the following algorithms.

Algorithm 2:

Constructing Preferred Hamming Product Code (HPC)

The code-block dimensions may be produced by the following:

Define a function P(x):

P(x)=5 if 1≦x≦11

P(x)=6 if 12≦x≦26

P(x)=7 if 27≦x≦57 (for x>57, P is not defined)

And the product code is: (n₁, k₁)×(n₂,k₂),

where n₁=k₁+P(k₁), n₂=k₂+P(k₂)

A few typical examples are as follows:

320=16*20 (40 bytes) R=0.559

480=20*24 (60 bytes) R=0.615

In order to take into account a desired minimum block interleaver size in a Hamming Product Code, the following algorithm can be utilized.

Algorithm 3:

Finding the block dimensions HPC(m1,m2,S1,S2) for a given data length and minimal interleaver length

Let K be the data length (in bits), and n and minimal interleaver length, then the algorithm finds a factorization K=k₁×k₂ such that the largest dimension of the resulting code-block is ≧n.

0. Define a function P(x):

P(x)=5 if 1≦x≦11

P(x)=6 if 12≦x≦26

P(x)=7 if 27≦x≦57 (for x>57—P is not defined)

1. Start with k₁=Round(Sqrt(K)), k₂=k₁.

2. If Reminder(K/k₁)=0 then:

k₂=K/k₁.

k=max(k₁,k₂), m=k+P(k)

if m≧n—FINISH (go to 7).

3. Set k₂=k₂−1.

4. If Reminder(K/k₂)=0 then:

k₁=K/k₂.

k=max(k₁,k₂), m=k+P(k)

if m≧n—FINISH (go to 7).

5. Set k₁=k₁+1.

6. If k₂>0 go to (2), else STOP: “Impossible interleaver length”.

7. Output k₁, k₂ and n₁=k₁+P(k₁), n₂=k₂+P(k₂)

Another family of variable length product codes with very high rate, k₁/k₁+1×k₂/k₂+1, is based on parity check product codes, PPC(k1,k2). This family is particularly efficient for delivering short IP packages through the channel.

It will be appreciated that product codes other than Hamming codes and PPC can alternatively be utilized in the present invention. For example, it is possible to use a 2-D Hamming Code with a Parity Check Product Code as the third dimension. Other non-limiting examples are non-linear codes. When Hamming codes are not used alone, algorithms 2 and 3 must be adjusted according to the actual product code selected.

Referring now to FIG. 2b, there is shown a block diagram illustration of a receiver capable of receiving and decoding the data transmitted by the transceiver of FIG. 2a. The receiver includes a demodulator 65 for demodulating the received signals, which are shaped in a filter 55, as known. The shaped signals are input to a unit 45 where the reliability is calculated for each bit in each detected symbol, along with the hard detected symbol (symbol to bit mapping). This input is provided to a variable length product decoder 35, which can perform hard decision decoding, soft decision decoding, or SISO iterative decoding. The choice of decoding method depends upon the computation capability which is available in the receiver unit for this particular data packet. It will be appreciated that the choice of decoding method is decided individually for each data packet, depending upon various criteria to assure the agreed upon quality of service, and channel conditions at the time of transmission.

The decoded data bits pass through a baseband interface 25, and a source decoder 15, and the data, substantially similar to the original data transmitted, is provided to the receiving unit.

One implementation of the present invention is a wireless communication system including a base station and a plurality of subscriber units. A transceiver including a variable length product encoder according to the invention is located in each subscriber. The base station includes a code selecting unit for selecting an optimal product code for encoding the data in each data packet a subscriber wishes to transmit. In this case, the product code is selected not only according to packet length, but also on the basis of measurement of the communication channel characteristics made by the receiver in the base station, and other pre-selected parameters. These parameters can include length of the data packet, and Quality of Service (QoS) terms of the subscriber, such as minimum data rate, efficiency of the code, and coding gain. It will be appreciated that a single long product code can be selected, which will protect the entire packet, with a level of protection which can be defined in advance. Alternatively, the packet can be fragmented into several smaller variable length packets, each of them protected by an appropriate product code. The final code can possibly be selected by the code selecting unit after completion of a handshake or negotiation procedure between the base station and the subscriber.

Once the code is selected, a set of parameters including the selected code are sent from the base station via the air interface to the transceiver in the subscriber unit to configure its error control scheme. The parameters that can be configured include: length of information packet (K bytes), code rate, bit-interleaver size. It will be appreciated that this implementation expands the conventional methodology of adaptive rate modulation described in the Background, by sending to the subscriber additional configuration parameters established for the communication to the subscriber.

In this implementation, the base station includes a powerful and complex decoder which receives the encoded data with added noise. The decoder must estimate the original data from the received information. The base station also includes a decoding method selecting unit, which is preferably a part of the receiver, and which decides, according to the QoS terms of the subscriber and the characteristics of the channel at the time of transmission, which decoding method to select for each transmitted data packet. The decoding method is selected from hard decision decoding, the simplest method having the lowest coding gain, soft decision decoding, which generally adds approximately 3 dB coding gain, and SISO (Soft-In/Soft-Out) iterative decoding, which generally also adds approximately an additional 3 dB coding gain, all of which are preferably available in the receiver of the base station.

The invention has several advantages over existing coding techniques that use shortened Reed-Solomon codes.

Flexibility is much higher than with Reed-Solomon codes. Unlike the Reed-Solomon coding scheme, which is limited in practice to a length of 256 bytes, longer packet sizes can be easily constructed with product codes. As an example, a packet size of 1500 bytes can be protected based on a single code word of 3-D code (31,25)×((39,32)×(16,15) with rate 0.62, or ((47,40)×(57,50)×(7,6) ) with rate 0.64.

Efficiency is much better for very short packages: The use of Reed-Solomon over a finite field with 256 elements, as used in many data protocols with correction capability of say 8 bytes, is not efficient for short packages, between 8 to 32 bytes. On the other hand, very high rate (k/k+1)² product codes are available for short packets.

Scalability of performance versus coding gain. Unlike Reed-Solomon codes for which complexity is not changed when shortening the codes, shortening of product codes decrease the main computation part related to soft decision decoding the component codes. Furthermore, the decoder can operate in one of a number of modes, while Reed-Solomon decoders are limited to hard decision decoding.

It will be appreciated by those skilled in the art that the present invention is not limited to what has been shown and described hereinabove by way of example. Rather, the scope of the invention is limited solely by the claims which follow.

1. A method for encoding data for transmission over a transmission channel in a digital communication system, the method comprising:
selecting an appropriate variable length product code for variable length data to be transmitted; and
encoding said data by means of said selected product code.

2. The method according to claim 1, wherein said variable length product code is selected in accordance with parameters selected from size of data packet, Quality of Service terms, and channel conditions at the time of transmission.

3. The method according to claim 1, further comprising transferring the encoded data packets over the transmission channel by means of a data protocol

4. The method according to claim 1, wherein the data is encoded in such a way as to provide scalable decoder complexity.

5. The method according to claim 1, wherein said step of encoding includes encoding data by means of a Hamming Product Code.

6. The method according to claim 1, wherein said step of encoding includes encoding data by means of a Parity Check Product Code.

7. The method according to claim 1, wherein the step of encoding includes selecting the product code by means of the following algorithm:
Algorithm 1:
Finding the preferred block dimensions for a given data length
Let K be the data length (in bits), then the algorithm finds a factorization K=k₁×k₂ such that for k₁≧k₂ the dimension ratio k₂/k₁ is maximum
1. Start with k₁=Round(Sqrt(K)), k₂=k₁.
2. If Reminder(K/k₁)=0 then k₂=K/k₁—FINISH (go to 7).
3. Set k₂=k₂−1.
4. If Reminder(K/k₂)=0 then k₁=K/k₂—FINISH (go to 7).
5. Set k₁=k+1.
6. If k₂>0 go to (2).
7. Output k₁, k₂.

8. The method according to claim 5, wherein the step of encoding includes selecting the product code by means of the following algorithm:
Algorithm 2:
Constructing Preferred Hamming Product Code (HPC)
The code-block dimensions may be produced by the following:
Define a function P(x):
P(x)=5 if 1≦x≦11
P(x)=6 if 12≦x≦26
P(x) =7 if 27≦x≦57 (for x>57, P is not defined)
And the product code is: (n₁, k₁)×(n₂,k₂),
where n₁=k₁+P(k₁), n₂=k₂+P(k₂)

9. The method according to claim 5, wherein the step of encoding includes selecting the product code by means of the following algorithm:
Algorithm 3:
Finding the block dimensions HPC(m1,m2,S1,S2) for a given data length and minimal interleaver length
Let K be the data length (in bits), and n and minimal interleaver length, then the algorithm finds a factorization K=k₁×k₂ such that the largest dimension of the resulting code-block is ≧n.
0. Define a function P(x):
P(x)=5 if 1≦x≦11
P(x)=6 if 12≦x≦26
P(x)=7 if 27≦x≦57 (for x>57—P is not defined)
1. Start with k₁=Round(Sqrt(K)), k₂=k₁.
2. If Reminder(K/k₁)=0 then:
k₂=K/k₁.
k=max(k₁,k₂), m=k+P(k)
if m≧n—FINISH (go to 7).
3. Set k₂=k₂−1.
4. If Reminder(K/k₂)=0 then:
k₁=K/k₂.
k=max(k₁,k₂), m=k+P(k)
if m≧n—FINISH (go to 7).
5. Set k₁=k₁+1.
6. If k₂>0 go to (2), else STOP: “Impossible interleaver length”.
7. Output k₁, k₂ and n₁32 k₁+P(k₁), n₂=k₂+P(k₂)

10. A system for encoding data for transmission over a transmission channel in a digital communication system, the system for encoding comprising:
a code selecting unit arranged to select a variable length code which is most suitable for variable length data to be encoded; and
an encoder encoding said variable length data with said selected variable length product code.

11. The system according to claim 10, further comprising means for providing parameters of said selected code to the encoder.

12. The system according to claim 10, wherein said code selecting unit includes means for receiving parameters selected from size of data packet, Quality of Service terms, and channel conditions in order to selected said selected code.

13. The system according to claim 10, further comprising:
a variable length product decoder arranged to decode said encoded data; and
a decoding method selecting unit for selecting, for a given data packet, a method of decoding from the group consisting of hard decision decoding, soft decision decoding, and iterative soft decision decoding.

14. The system according to claim 10, wherein:
said digital communication system includes a base station and at least one subscriber unit; and
the encoder is mounted in said subscriber unit;
wherein said base station includes:
a code selecting unit arranged to select a variable length product code which is most suitable for variable length data to be encoded; and
a transceiver for transmitting parameters of said selected code to said encoder in said subscriber unit.

15. The system according to claim 14, wherein said base station further comprises:
a variable length product decoder arranged to decode said encoded data; and
a decoding method selecting unit for selecting a method of decoding for the variable length product decoder from the group consisting of hard decision decoding, soft decision decoding, and iterative soft decision decoding.

16. A data decoder comprising:
a variable length product decoder, including apparatus for performing hard decision decoding, soft decision decoding, and SISO iterative decoding; and a mechanism for selecting one of said methods of decoding for a received data packet.
